(19) United States
(12) Patent Application Publication
(10) Pub. No.: US 2008/0318345 A1
(43) Pub. Date: Dec. 25, 2008

(54) PLASMA ION IMPLANTATION PROCESS CONTROL USING REFLECTOMETRY

(76) Inventors: Harold M. Persing, Westbrook, ME (US); Vikram Singh, North Andover, MA (US); Edwin Arevalo, Haverhill, MA (US)

Correspondence Address: Scott Faber, Esq.;Varian Semiconductor Equipment Associates, Inc, 35 Dory Road, Gloucester, MA, 01930, US

(21) Appl. No.: 11/766,984

(22) Filed: Jun. 22, 2007

(51) Int. Cl. H01L 21/265; G01B 9/02; G21K 5/00

(52) U.S. Cl. 438/7; 250/492.21; 356/448; 257/E21.334

(57) ABSTRACT

An approach that determines an ion implantation processing characteristic in a plasma ion implantation of a substrate is described. In one embodiment, there is a light source configured to direct radiation onto the substrate. A detector is configured to measure radiation reflected from the substrate. A processor is configured to correlate the measured radiation reflected from the substrate to an ion implantation processing characteristic.

### BACKGROUND

This disclosure relates generally to plasma ion implantation of substrates, and more specifically to measuring the dosage of ions in a plasma ion implantation of a substrate using reflectometry.

Ion implantation is a standard technique for introducing conductivity-altering impurities into substrates such as semiconductor wafers. In a conventional beamline ion implantation system, a desired impurity material is ionized in an ion source, the ions are accelerated to form an ion beam of prescribed energy, and the ion beam is directed at the surface of a semiconductor substrate. Energetic ions in the beam penetrate into the bulk of the semiconductor material and are embedded into the crystalline lattice of the semiconductor material to form a region of desired conductivity.

Plasma ion implantation is a different approach to ion implantation that has demonstrated the capability of implanting ions in either planar semiconductor structures or three-dimensional (3-D) semiconductor structures such as “Fin-FETs”. In a typical plasma ion implantation system, a semiconductor substrate is placed on a platen that is positioned within a process chamber. An ionizable process gas containing the desired dopant material is introduced into the process chamber, and the process gas is ionized, forming a plasma. A voltage pulse applied between the platen and an anode creates a plasma sheath in the vicinity of the substrate. Eventually, the applied voltage pulse causes ions in the plasma to cross the plasma sheath and implant into the substrate.

There can be one or more Faraday cups positioned adjacent to the platen for measuring the ion dose implanted into the substrate. In particular, the Faraday cups are spaced around the periphery of the substrate to intercept and count samples of positive ions accelerated from the plasma toward the substrate. Positive ions entering each Faraday cup produce a current in an electrical circuit connected to the cup that is representative of ion current impinging on the substrate. A dose processor or other dose monitoring circuit receives the electrical current measurements from the Faraday cups and determines an ion dose from the current measurements.

The current approach of using Faraday cups to monitor the dose of ions is not perfectly suited for plasma ion implantations because the Faraday cups count all ions formed from the process gas and cannot distinguish between the dopant ions. For example, if BF₃ is the process gas, then it can dissociate into B, BF, BF₂, F and F₂ ions during the plasma ion implantation; however, only the B, BF, BF₂ ions provide the dopant (boron) for the implant. Because the Faradays cups will count the F and F₂ ions along with the B, BF, BF₂ ions, it is difficult to provide a one-to-one correspondence between counted ions and implantation dose. Also, the Faraday cup monitoring method accounts for only ions accelerated through the plasma sheath, normal to the substrate. A means of measuring ion dose on the sidewalls (rather than the tops and bottoms) of 3-D semiconductor structures is necessary when fabricating such devices.

Therefore, it is desirable to develop a methodology that can better measure dopant ions implanted on a substrate and thus provide more control in a plasma ion implantation.

### SUMMARY

In a first embodiment, there is a method for determining an ion implantation processing characteristic in a plasma ion implantation of a substrate. In this embodiment, the method comprises directing radiation onto the substrate; measuring radiation reflected from the substrate; and correlating the measured radiation reflected from the substrate to an ion implantation processing characteristic.

In a second embodiment, there is a method for monitoring dosage of ions implanted in a substrate during a plasma ion implantation of the substrate. In this embodiment, the method comprises directing radiation onto the substrate during the plasma ion implantation; measuring radiation reflected from the substrate; and correlating the measured radiation reflected from the substrate to a dosage of ions implanted in the substrate.

In a third embodiment, there is a method for determining dosage of ions in a plasma ion implantation of a substrate. In this embodiment, the method comprises removing the substrate from a process chamber after the plasma ion implantation; directing radiation onto the substrate; measuring radiation reflected from the substrate; and correlating the measured radiation reflected from the substrate to a dosage of ions implanted during the plasma ion implantation of the substrate.

In a fourth embodiment, there is a system for determining an ion implantation processing characteristic in a plasma ion implantation of a substrate. In this embodiment, there is a light source configured to direct radiation onto the substrate. A detector is configured to measure radiation reflected from the substrate. A processor is configured to correlate the measured radiation reflected from the substrate to an ion implantation processing characteristic.

In a fifth embodiment, there is a plasma ion implantation system. In this embodiment, there is a process chamber configured to receive a substrate for plasma ion implantation. A light source is configured to direct radiation into the process chamber onto the substrate during the plasma ion implantation. A detector is configured to measure radiation reflected from the substrate through the process chamber. A processor is configured to correlate the measured radiation reflected from the substrate to a dosage of ions implanted in the substrate.

In a sixth embodiment, there is a plasma ion implantation system. In this embodiment, there is a process chamber configured to receive a substrate for plasma ion implantation. A transfer chamber is configured to receive the substrate after performing the plasma ion implantation in the process chamber. A light source is configured to direct radiation into the transfer chamber onto the substrate. A detector is configured to measure radiation reflected from the substrate through the transfer chamber. A processor is configured to correlate the measured radiation reflected from the substrate to a dosage of ions implanted in the substrate.

### BRIEF DESCRIPTION OF THE DRAWINGS

FIG. 1 shows a schematic of a conventional plasma ion implantation system;

FIG. 2 shows a simplified schematic of a plasma ion implantation system according to one embodiment of this disclosure;

FIG. 3 shows a simplified schematic of a plasma ion implantation system according to a second embodiment of this disclosure;

FIG. 4 shows a simplified schematic of a plasma ion implantation system according to a third embodiment of this disclosure;

FIG. 5 shows a simplified schematic of a plasma ion implantation system according to a fourth embodiment of this disclosure;

FIG. 6 depicts a flow chart describing a method for determining dosage of ions with the plasma ion implantation systems shown in FIGS. 2 and 3 according to one embodiment of this disclosure; and

FIG. 7 depicts a flow chart describing a method for determining dosage of ions with the plasma ion implantation system shown in FIGS. 4 and 5 according to one embodiment of this disclosure.

### DETAILED DESCRIPTION

Embodiments of this disclosure are directed to a technique for using reflectometry to determine dosage of ions in a plasma ion implantation of a substrate that can include either planar semiconductor structures or 3-D semiconductor structures. In one embodiment, dosage of ions can be determined in-situ (i.e., inside a process chamber) and in another embodiment the dosage of ions are determined outside the process chamber. In one embodiment of the in-situ representation, radiation is directed onto the substrate at a normal angle of incidence during the plasma ion implantation and radiation that is reflected at a normal angle of incidence from the substrate is measured. In a second embodiment of the in-situ representation, radiation is directed onto the substrate at an oblique angle of incidence during the plasma ion implantation and radiation that is reflected at an oblique angle of incidence from the substrate is measured. For the representation where the dosage of ions is determined outside the process chamber, radiation is directed onto the substrate at a normal angle of incidence after completing the plasma ion implantation and radiation reflected from the substrate at a normal angle of incidence is measured. In another embodiment, radiation is directed onto the substrate at an oblique angle of incidence and radiation that is reflected at an oblique angle of incidence from the substrate is measured. In each of these embodiments, the dosage of ions is determined by correlating the measured radiation reflected from the substrate to a dosage of ions implanted in the substrate.

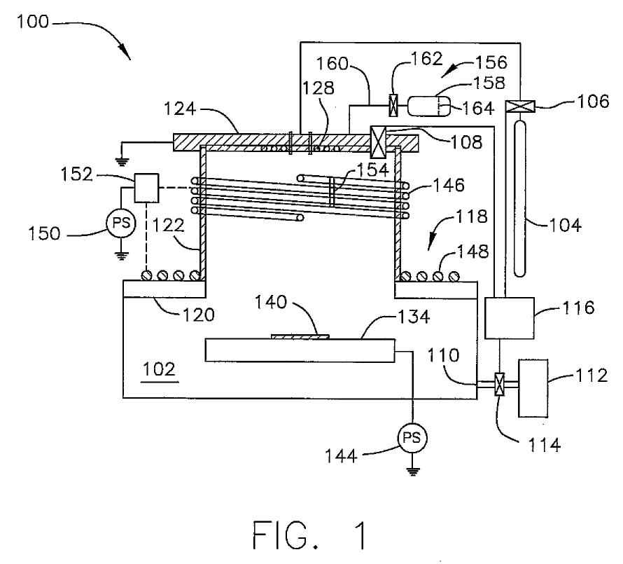

FIG. 1 shows a schematic of a conventional plasma ion implantation system. In particular, FIG. 1 shows a plasma immersion ion implantation system 100. Although the plasma ion implantation system described in FIG. 1 and in the embodiments that relates to this disclosure is a plasma immersion ion implantation system, the scope of this disclosure is applicable to other plasma ion implantation systems. Referring back to FIG. 1, plasma ion implantation system 100 comprises a plasma process chamber 102 that defines an enclosed volume. A gas source 104, coupled to the plasma process chamber 102 through a proportional valve 106, supplies a process gas to the chamber. A pressure gauge 108 measures the pressure inside the chamber 102. A vacuum pump 112 evacuates exhausts from the plasma process chamber 102 through an exhaust port 110 in the chamber. An exhaust valve 114 controls the exhaust conductance through the exhaust port 110.

The plasma immersion ion implantation system 100 further includes a gas pressure controller 116 that is electrically connected to the proportional valve 106, the pressure gauge 108, and the exhaust valve 114. The gas pressure controller 116 maintains the desired pressure in the plasma process chamber 102 by controlling either the exhaust conductance with the exhaust valve 114 or controlling the process gas flow rate with the proportional valve 106 in a feedback loop that is responsive to the pressure gauge 108.

FIG. 1 shows that the plasma process chamber 102 has a chamber top 118 that includes a first section 120 formed of a dielectric material that extends in a generally horizontal direction. A second section 122 of the chamber top 118 is formed of a dielectric material that extends at a height from the first section 120 in a generally vertical direction.

The dielectric materials in the first and second sections 120, 122 provide a medium for transferring radio frequency (RF) power from RF antennas 146, 148 to plasma that forms inside the chamber 102. In one embodiment, the dielectric material used to form the first and second sections 120, 122 is a high purity ceramic material that is chemically resistant to the process gases and that has good thermal properties.

The chamber top 118 as shown in FIG. 1 further includes a top section 124 formed of an electrically and thermally conductive material that extends a length across the second section 122 in the horizontal direction. In one embodiment, the conductive material used to form the top section 124 is aluminum. Also, in another embodiment, the thermal and electrical conductivities of the material used to form the top section 124 are high enough to dissipate the heat load and to minimize charging effects that results from secondary electron emission. Typically, the conductive material used to form the top section 124 is chemically resistant to the process gases.

In one embodiment, the top section 124 comprises a cooling system that regulates the temperature of the top section 124 in order to further dissipate the heat load generated during processing. As shown in FIG. 1, the cooling system can be a fluid cooling system that includes cooling passages 128 in the top section 124 that circulate a liquid coolant from a coolant source.

The plasma immersion ion implantation system 100 shown in FIG. 1 further includes a platen 134 positioned in the plasma process chamber 102 at a predetermined height below the top section 124 of the chamber top 118 and at a predetermined height below the first section 120 of the chamber top 118. The platen 134 can be a substrate holder that holds a substrate 140 such as a semiconductor wafer for ion implantation.

A bias voltage power supply 144 is electrically connected to the platen 134. The bias voltage power supply 144 biases the platen 134 at a voltage that attracts ions in the plasma to the substrate 140. The bias voltage power supply 144 can be a DC power supply or a RF power supply.

Although not shown in FIG. 1, there are one or more Faraday cups positioned in the platen 134 for measuring the ion dose implanted into the substrate 140. Typically, Faraday cups are equally spaced around the periphery of the substrate. Each Faraday cup comprises a conductive enclosure having an entrance facing the plasma. Each Faraday cup is preferably positioned as close as is practical to the substrate and intercepts a sample of the positive ions accelerated from the plasma toward the platen.

The Faraday cups are generally electrically connected to a dose processor or other dose monitoring circuit (not shown). Positive ions entering each Faraday cup through the entrance produce in the electrical circuit connected to the Faraday cup a current that is representative of the impinging ion current. The dose processor may process the electrical current to determine ion dose.

FIG. 1 shows that a RF source 150, such as a RF power supply, is electrically connected to at least one of the planar coil antenna 146 and the helical coil antenna 148. The RF source 150 is coupled to the RF antennas 146, 148 by an impedance matching network 152 that maximizes the power transferred from the RF source 150 to the RF antennas 146, 148. Dashed lines from the output of the impedance matching network 152 to the planar coil antenna 146 and the helical coil antenna 148 are used to indicate that electrical connections can be made from the output of the impedance matching network 152 to either or both of the planar coil antenna 146 and the helical coil antenna 148. In addition, a coil adjuster 154 is used with antenna 146 to change the effective number of turns in the coil.

The RF source 150 and impedance matching network 152 resonates RF currents in the RF antennas 146, 148. The RF current in the RF antennas 146, 148 induces RF currents into the plasma process chamber 102. The RF currents in the plasma process chamber 102 excite and ionize the process gas to generate and maintain a plasma in the chamber.

FIG. 1 shows that the plasma immersion ion implantation system 100 further includes a plasma igniter 156. The plasma igniter 156 includes a reservoir 158 of strike gas, which is a highly-ionizable gas, such as argon (Ar), that assists in igniting the plasma. The reservoir 158 can be a relatively small reservoir of known volume and known pressure. The reservoir 158 is coupled to the plasma process chamber 102 with a high conductance gas connection 160. A burst valve 162 isolates the reservoir 158 from the chamber 102.

In operation, the plasma process chamber 102 is evacuated to high vacuum. The process gas is then introduced into the plasma process chamber 102 by the proportional valve 106 and exhausted from the chamber by the vacuum pump 112. The gas pressure controller 116 is used to maintain the desired gas pressure for a desired process gas flow rate and exhaust conductance.

The RF source 150 generates a RF signal that is applied to the RF antennas 146, 148. The RF signal applied to the RF antennas 146, 148 generates a RF current in the RF antennas 146, 148. Electromagnetic fields induced by the RF currents in the RF antennas 146, 148 couple through at least one of the dielectric material forming the first section 120 and the dielectric material forming the second section 122 and into the plasma process chamber 102.

The electromagnetic fields induced in the plasma process chamber 102 excite and ionize the process gas molecules. Plasma ignition occurs when a small number of free electrons move in such a way that they ionize some process gas molecules. The ionized process gas molecules release more free electrons that ionize more gas molecules. This ionization process continues until a steady state of ionized gas and free electrons are present in the plasma. The characteristics of the plasma can be tuned by changing the effective number of turns in the parasitic antenna coil with the coil adjuster 154. The implantation of plasma ions into the target substrate 140 is then achieved by providing a negative voltage to the target.

Additional details of a plasma immersion ion implantation system are provided in US Patent Application Publication No. 2005/0205212.

As mentioned above, using Faraday cups to monitor the dose of ions is not ideally suited for plasma ion implantation systems because the Faraday cups count all ions formed from the process gas and cannot distinguish between the dopant ions. Another issue associated with using Faraday cups to monitor the dose of ions is that the cups account for only ions accelerated through the plasma sheath, normal to the substrate and thus are not conducive to measuring ion dose on the sidewalls of 3-D semiconductor structures that include but are not limited to FinFets when fabricating such devices. In this disclosure, the issues associated with using Faraday cups in a plasma ion implantation system is overcome by using a reflectometry measuring technique to determine indirectly the dosage of ions implanted in a substrate. Below are details of this reflectometry measuring technique and the various embodiments in which this technique can be used.

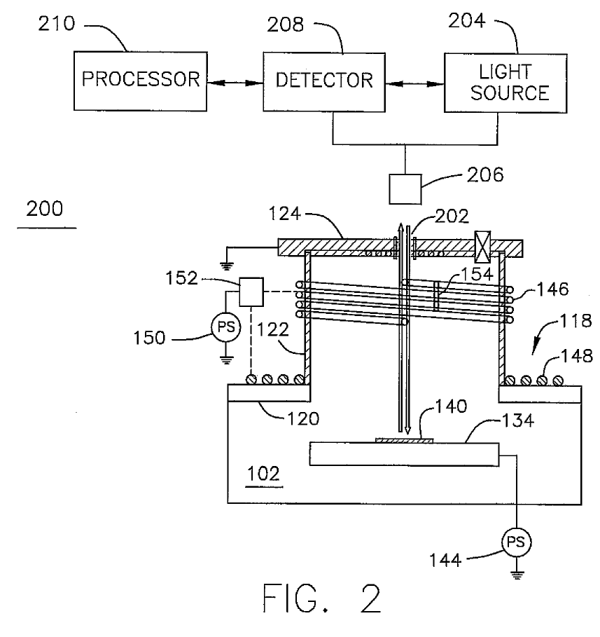

FIG. 2 shows a simplified schematic of a plasma ion implantation system 200 according to one embodiment of the disclosure. The plasma ion implantation system 200 is a plasma immersion ion implantation system like the one shown in FIG. 1. Because the plasma ion implantation system 200 is similar to the system 100 shown in FIG. 1, the description that follows is directed only to the reflectometry measuring technique and not to the individual components of the plasma immersion ion implantation system, which are essentially the same as the ones described above for system 100. It should be noted that the reflectometry measuring technique does not preclude or replace using Faraday cups. Those skilled in the art will recognize that the Faraday cups can be used in concert with the reflectometry measuring technique.

Referring to FIG. 2, the top section 124 of the chamber top 118 has a window 202 formed therein that permits a light source 204 to direct radiation into the process chamber 102 via a collimator 206 onto the substrate 140 during the plasma ion implantation. In this embodiment, the light source 204 is configured to direct the radiation onto the substrate 140 at a normal angle of incidence. A detector 208 receives radiation reflected from the substrate 140 through the window 202 in the process chamber 102 and the collimator 206. In this embodiment, the detector 208 is configured to measure radiation reflected at a normal angle of incidence from the substrate 140.

In one embodiment, the light source 204 is a Xenon flashlamp which provides a bright, pulsed, broadband source of radiation. Those skilled in the art will recognize that other pulsed light sources are suitable for use with this disclosure. In one embodiment, the detector 208 is a spectrometer that uses a charge-coupled device (CCD) to detect the reflected radiation. Those skilled in the art will recognize that other types of light detectors that have a dynamic range of radiation detection capability are suitable for use with this disclosure. In addition, although FIG. 2 shows that the light source 204 and detector 208 are separate from each other, it is possible to have the light source and detector integrated into one single unit such as the Spectral Reflectometer SP2003 provided by Verity Instrument, Inc.

Referring back to FIG. 2, a processor 210 such as a signal processor receives the radiation measured by the detector 208 and is configured to correlate the measured radiation reflected from the substrate to a dosage of ions implanted in the substrate. In one embodiment, the processor 210 is configured to compare the measured radiation to a previously determined reflectance signature that is representative of a desired dose for the plasma ion implantation. In one embodiment, a look-up table is used to store a plurality of reflectance signatures each corresponding to a desired dosage for use in a plasma ion implantation. In this embodiment, the processor 210 receives the reflectance measurement from the detector 208 and compares it to the reflectance signature stored in the look-up table that corresponds to the dosage desired for the plasma ion implantation and determines whether there is a match.

As used herein, a match arises when the reflectance measurement is the same as the stored reflectance signature or if there is an acceptable amount of error between the reflectance measurement and the stored reflectance signature. If the processor 210 determines that there is not a match then the processor is configured to generate a control signal to continue the plasma ion implantation of the substrate. Alternatively, if the processor 210 determines that there is a match then the processor is configured to generate a control signal to stop the plasma ion implantation of the substrate.

The processor 210 can make the correlation from the measured radiation reflected from the substrate to a dosage of ions implanted in the substrate because this disclosure has recognized through empirical studies that there is a relationship between the known dose and energy of an implant. In particular, the reflectance is a convolution of the energy and dose of the implanted ions, the type of substrate being implanted, and the surface characteristics of the substrate (e.g., type, depth and percent coverage of photo-resist). These effects on the reflectance must be empirically de-convolved and then “taught” to the processor 210. A reflectance measurement taken prior to the implant will provide a baseline measurement which can be used to help de-convolve the surface characteristics of the substrate. Therefore, with this knowledge, algorithms can be developed by those skilled in the art that can use empirical data to determine what a reflectance signature should be for a desired dosage for a plasma ion implantation. As a result, a look-up table can be built that contains various reflectance signatures for various dosages used in a plasma ion implantation.

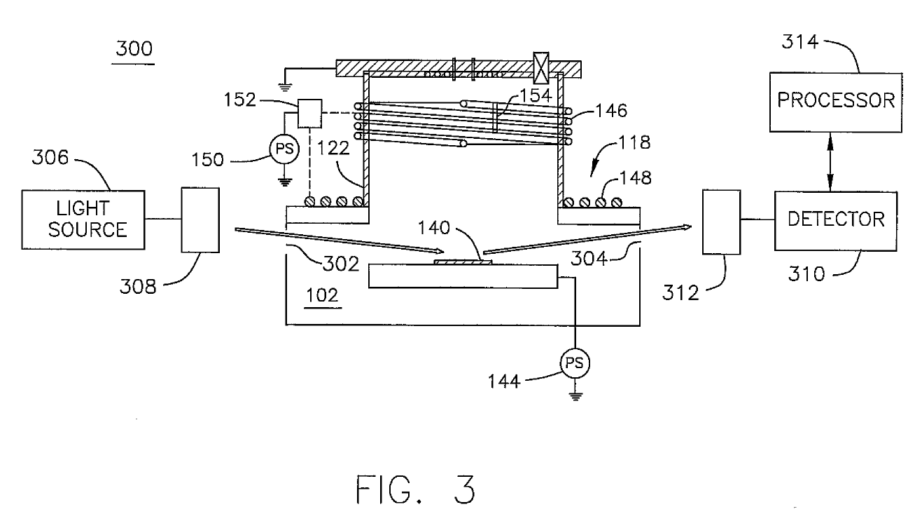

FIG. 3 shows a simplified schematic of a plasma ion implantation system 300 according to another in-situ embodiment. In this embodiment, the plasma ion implantation system 300 has window 302 and 304 formed in lower section of the process chamber 102. In particular, windows 302 and 304 are formed in the sides of process chamber 102 such that a light source 306 directs radiation into the window 302 via a collimator 308 and onto the substrate 140 during the plasma ion implantation. In this embodiment, the light source 306 is configured to direct the radiation onto the substrate 140 at an oblique angle of incidence. A detector 310 receives radiation reflected from the substrate 140 through the window 304 via a collimator 312. In this embodiment, the detector 310 is configured to measure radiation reflected at an oblique angle of incidence from the substrate 140.

A processor 314 receives the radiation measured by the detector 310 and is configured to correlate the measured radiation reflected from the substrate to a dosage of ions implanted in the substrate. In one embodiment, the processor 314 is configured to compare the measured radiation to a previously determined reflectance signature that is representative of a desired dose for the plasma ion implantation. In this embodiment, a look-up table is used to store a plurality of reflectance signatures each corresponding to a desired dosage for use in a plasma ion implantation. If the processor 314 determines that there is not a match then the processor is configured to generate a control signal to continue the plasma ion implantation of the substrate. Alternatively, if the processor 314 determines that there is a match then the processor is configured to generate a control signal to stop the plasma ion implantation of the substrate.

Except for the configuration shown in FIG. 3, the light source 306, collimators 308 and 312, detector 310 and processor 314 are similar to the light source 204, collimator 206, detector 208 and processor 210 shown in FIG. 2. As a result, separate descriptions of these elements are not provided.

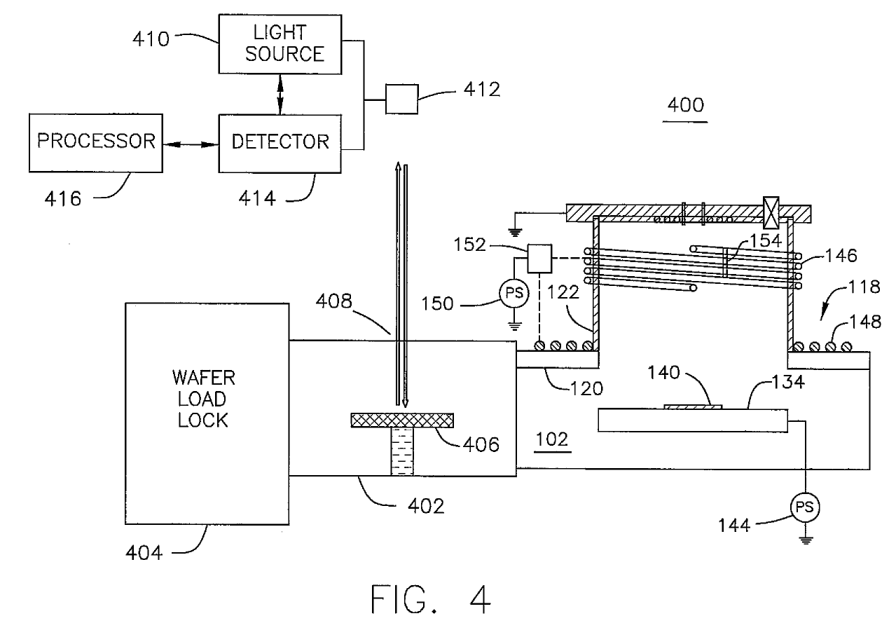

FIG. 4 shows a simplified schematic of a plasma ion implantation system 400 for the embodiment where the dosage of ions is determined outside the process chamber 102 after the plasma ion implantation has been completed. In this embodiment, the dosage of ions is determined after the substrate 140 has been removed from the platen 134 in the process chamber 102 into a transfer chamber 402 that is located between a wafer load lock 404 and the process chamber. In operation, the wafer load lock 404 which is a transport mechanism, removes a substrate from a loading cassette or holder (not shown) and introduces it to the transfer chamber 402. The transfer chamber 402 includes an orienter 406 that receives the substrate 140 from the load lock 404 and ensures that the azimuthal location or azimuthal positioning is the same each time. Once the orientation is in order, the load lock 404 transfers the substrate 140 from the transfer chamber 402 to the process chamber 102 for plasma ion implantation. After the plasma ion implantation has been completed, the load lock 404 transfers the substrate 140 back to the orienter 406 in the transfer chamber 402.

As shown in FIG. 4, the transfer chamber 402 includes a window 408 formed in a top section of the transfer chamber. A light source 410 directs radiation into the window 408 via a collimator 412 and onto the substrate 140 held by the orienter 406. In this embodiment, the light source 410 is configured to direct the radiation onto the substrate 140 at a normal angle of incidence. A detector 414 receives radiation reflected from the substrate 140 through the window 408 via the collimator 412. In this embodiment, the detector 414 is configured to measure radiation reflected at a normal angle of incidence from the substrate 140.

A processor 416 receives the radiation measured by the detector 414 and is configured to correlate the measured radiation reflected from the substrate to a dosage of ions implanted in the substrate. In one embodiment, the processor 416 is configured to compare the measured radiation to a previously determined reflectance signature that is representative of a desired dose for the plasma ion implantation. In this embodiment, a look-up table is used to store a plurality of reflectance signatures each corresponding to a desired dosage for use in a plasma ion implantation.

As in the previous embodiments, the light source 410, collimator 412, detector 414 and processor 416 are similar to the ones shown in FIGS. 2 and 3. As a result, separate descriptions of these elements are not provided.

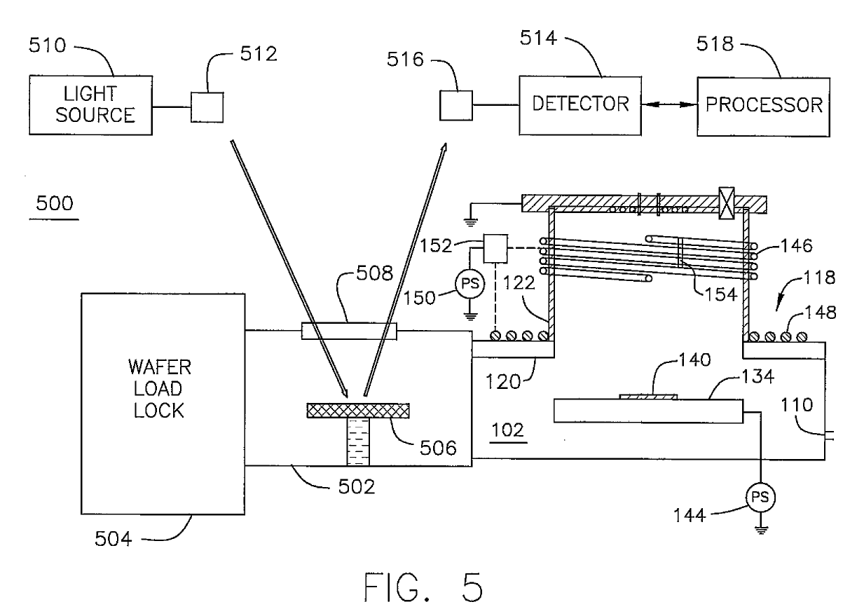

FIG. 5 shows another embodiment where the dosage of ions is determined inside the transfer chamber. In particular, FIG. 5 shows a simplified schematic of a plasma ion implantation system 500 where the dosage of ions is determined outside the process chamber 102 after the plasma ion implantation has been completed. In this embodiment, radiation is directed onto the substrate at an oblique angle of incidence via a light source 510 and a collimator 512 and radiation that is reflected at an oblique angle of incidence from the substrate is measured via a detector 514 and collimator 516. More specifically, FIG. 5 shows that a transfer chamber 502 includes a window 508 formed in a top section of the transfer chamber. The light source 510 directs radiation into the window 508 via the collimator 512 and onto the substrate 140 held by the orienter 506.

A processor 518 receives the radiation measured by the detector 514 and is configured to correlate the measured radiation reflected from the substrate to a dosage of ions implanted in the substrate. In one embodiment, the processor 518 is configured to compare the measured radiation to a previously determined reflectance signature that is representative of a desired dose for the plasma ion implantation. In this embodiment, a look-up table is used to store a plurality of reflectance signatures each corresponding to a desired dosage for use in a plasma ion implantation.

As in the previous embodiments, the light source 510, collimators 512 and 516, detector 514 and processor 518 are similar to the ones shown in FIGS. 2, 3 and 4. As a result, separate descriptions of these elements are not provided.

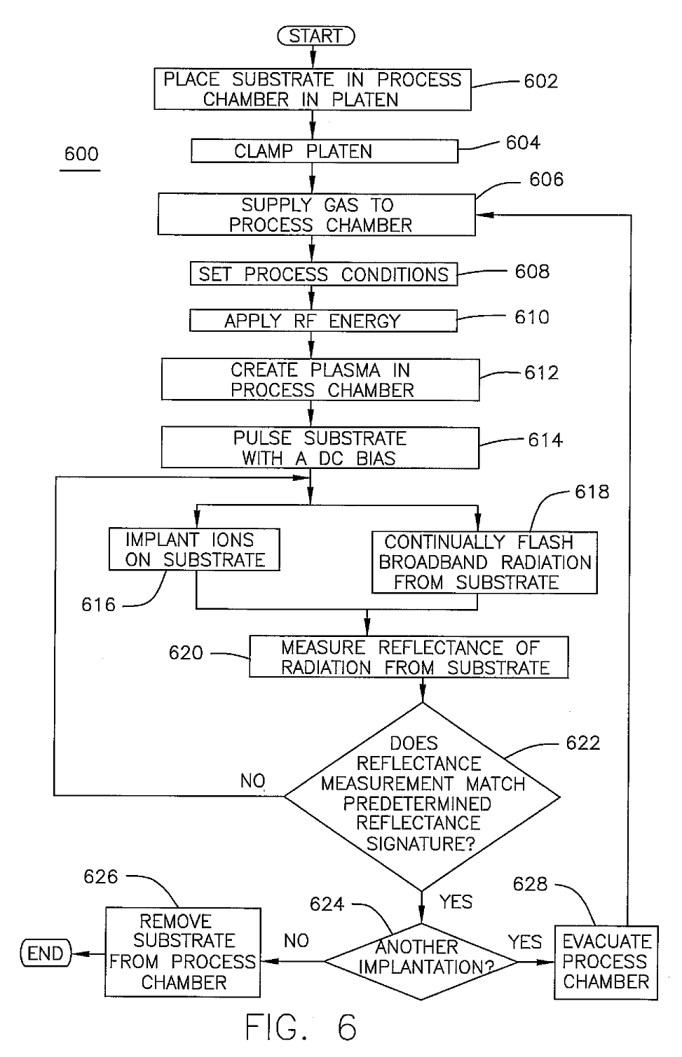

FIG. 6 depicts a flow chart 600 describing a method for determining dosage of ions for the in situ embodiments (FIGS. 2 and 3). The method begins at 602 where a substrate is placed in the process chamber and positioned on the platen. The platen is clamped at 604, gas is supplied into the process chamber at 606 and process conditions are set at 608. The RF energy source generates RF energy at 610. In particular, the RF source and impedance matching network resonate RF currents in the antennas which induce electromagnetic fields within the plasma process chamber. The electromagnetic fields induced in the plasma process chamber excite and ionize process gas molecules. Plasma is created in the chamber at 612 when a small number of gas molecules move in such a way that they ionize some of the process gas molecules. The ionized process gas molecules release more free electrons that ionize more gas molecules. Eventually, this ionized process results in a steady state of ionized gas and free electrons that are present in plasma. The substrate is pulsed with a negative DC bias at 614. Applying the DC bias will create an electric field that accelerates the positive ions from the plasma across the plasma sheath toward the platen. The accelerated ions are subsequently implanted into the substrate at 616 to form regions of impurity material.

During plasma ion implantation, the substrate is continually monitored for the amount of dopant being implanted. In particular, the light source pulses broadband radiation onto the substrate at 618 both prior to and during the implant. The detector measures the reflectance of radiation from the substrate at 620. At 622, the processor determines whether the reflectance measurement matches the predetermined reflectance signature that corresponds to the dosage specified for the plasma ion implantation. If the processor determines at 622 that the reflectance measurement does not match the predetermined reflectance signature, then implantation continues at 616 as does pulsing of the broadband radiation on the substrate at 618 and measurement of reflectance at 620.

Alternatively, if the processor determines at 622 that the reflectance measurement does match the predetermined reflectance signature, then another decision is made at 624. In particular, a decision is made regarding whether one wants to perform another ion implantation. If no more implants are desired, then the substrate is removed from the plasma process chamber at 626 for further processing and is eventually later cut into individual integrated circuits after subsequent processing. Alternatively, if another implant is desired, then the process chamber is evacuated at 628 and another implant process at a specified dopant rate is initiated and process acts 606-624 are repeated at desired process conditions.

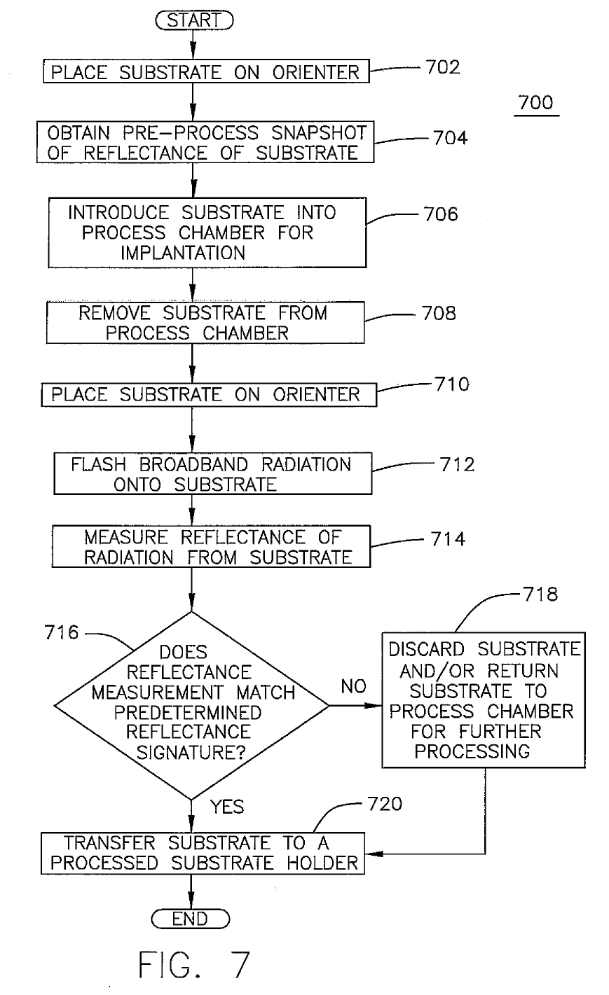

FIG. 7 shows a flow chart 700 describing a method for determining dosage of ions for the embodiment where the dosage of ions is determined outside the process chamber 102 after the plasma ion implantation has been completed. The method begins at 702 where a substrate is placed onto the orienter in the transfer chamber. A pre-process “snapshot” of the reflectance is taken of the substrate at 704. The substrate is introduced to the process chamber at 706 and implanted per the method(s) previously described in FIG. 6. The method continues at 708 where a substrate is removed from the process chamber. In particular, the transport mechanism transfers the substrate to the transfer chamber and places it on the orienter at 710. The light source pulses broadband radiation through the window in the transfer chamber onto the substrate at 712. The detector measures the reflectance of radiation from the substrate at 714. At 716, the processor determines whether the reflectance measurement matches the predetermined reflectance signature that corresponds to the dosage specified for the plasma ion implantation.

If the processor determines at 716 that the reflectance measurement does not match the predetermined reflectance signature, then the operator of the ion implantation has the option at 718 to either discard the substrate or return it to the plasma ion implantation system for further ion implantation. Alternatively, if the processor determines at 716 that the reflectance measurement does match the predetermined reflectance signature, then the substrate is unclamped from the orienter, removed from the transfer chamber and transferred to a substrate holder that stores processed substrates at 720.

The foregoing flow charts shows some of the processing functions associated with using reflectometry to determine dosage of ions in a plasma ion implantation of a substrate according to several embodiments of this disclosure. In this regard, each block represents a process act associated with performing these functions. It should also be noted that in some alternative implementations, the acts noted in the blocks may occur out of the order noted in the figure or, for example, may in fact be executed substantially concurrently or in the reverse order, depending upon the act involved. Also, one of ordinary skill in the art will recognize that additional blocks that describe the processing functions may be added.

Although the reflectometry technique has been described has having utility for determining dosage of ions in a plasma ion implantation of a substrate, this technique has applicability in other embodiments related to ion implantation. For example, the above-described reflectometry technique can be used in a pre-amorphization implantation process and a strain altering implantation process to determine when a desired depth (and dose) of a pre-amorphization or strain has been attained.

In this embodiment, the reflectometry technique that uses normal incidences of light is used to determine depth. In particular, a light source will direct radiation at a normal angle of incidence into a window formed in the process chamber via a collimator onto the substrate held by the platen. A detector receives radiation reflected at a normal angle of incidence from the substrate through the window in the process chamber via the collimator.

A processor receives the radiation measured by the detector and is configured to correlate the measured radiation reflected from the substrate to a depth that the ions have been implanted in the substrate. As with the embodiments described above for determining ion dosage, the processor is configured to compare the measured radiation to a previously determined reflectance signature that is representative of a desired depth for the plasma ion implantation. In this embodiment, a look-up table is used to store a plurality of reflectance signatures each corresponding to a desired depth (and/or dose) for use in a plasma ion implantation.

Although heretofore, the determining of dosage and depth in a substrate undergoing a plasma ion implantation has been described with reference to using reflectometry, those skilled in the art will recognize that other approaches can be used to determine these and other ion implantation processing characteristics. For example, ellipsometry, interferometry and scatterometry can be used to determine ion implantation processing characteristics (e.g., ion dosage, depth, etc. of a substrate undergoing a plasma ion implantation.

It is apparent that there has been provided with this disclosure an approach that provides plasma ion implantation process control using reflectometry. While the disclosure has been particularly shown and described in conjunction with a preferred embodiment thereof, it will be appreciated that variations and modifications will occur to those skilled in the art. Therefore, it is to be understood that the appended claims are intended to cover all such modifications and changes as fall within the true spirit of the invention.

What is claimed is:

1. A method for determining an ion implantation processing characteristic in a plasma ion implantation of a substrate, comprising:
directing radiation onto the substrate;
measuring radiation reflected from the substrate; and
correlating the measured radiation reflected from the substrate to an ion implantation processing characteristic.

2. The method according to claim 1, wherein the directing of radiation onto the substrate comprises directing the radiation onto the substrate at a normal angle of incidence during the plasma ion implantation.

3. The method according to claim 2, wherein the measuring of radiation reflected from the substrate comprises measuring radiation reflected at a normal angle of incidence from the substrate.

4. The method according to claim 1, wherein the directing of radiation onto the substrate comprises directing the radiation onto the substrate at an oblique angle of incidence during the plasma ion implantation.

5. The method according to claim 4, wherein the measuring of radiation reflected from the substrate comprises measuring radiation reflected at an oblique angle of incidence from the substrate.

6. The method according to claim 1, wherein the directing of radiation onto the substrate comprises directing the radiation onto the substrate at a normal angle of incidence before and after completing the plasma ion implantation.

7. The method according to claim 6, wherein the measuring of radiation reflected from the substrate comprises measuring radiation reflected at a normal angle of incidence from the substrate.

8. The method according to claim 1, wherein the directing of radiation onto the substrate comprises directing the radiation onto the substrate at an oblique angle of incidence before and after completing the plasma ion implantation.

9. The method according to claim 8, wherein the measuring of radiation reflected from the substrate comprises measuring radiation reflected at an oblique angle of incidence from the substrate.

10. The method according to claim 1, wherein the correlating of the measured radiation reflected from the substrate to an ion implantation processing characteristic comprises comparing the measured radiation to a previously determined reflectance signature that corresponds to a desired ion implantation processing characteristic.

11. A method for monitoring dosage of ions implanted in a substrate during a plasma ion implantation of the substrate, comprising:
directing radiation onto the substrate during the plasma ion implantation;
measuring radiation reflected from the substrate; and
correlating the measured radiation reflected from the substrate to a dosage of ions implanted in the substrate.

12. The method according to claim 11, wherein the directing of radiation onto the substrate comprises directing the radiation onto the substrate at a normal angle of incidence.

13. The method according to claim 12, wherein the measuring of radiation reflected from the substrate comprises measuring radiation reflected at a normal angle of incidence from the substrate.

14. The method according to claim 11, wherein the directing of radiation onto the substrate comprises directing the radiation onto the substrate at an oblique angle of incidence.

15. The method according to claim 14, wherein the measuring of radiation reflected from the substrate comprises measuring radiation reflected at an oblique angle of incidence from the substrate.

16. The method according to claim 11, wherein the correlating of the measured radiation reflected from the substrate to a dosage of ions comprises comparing the measured radiation to a previously determined reflectance signature that corresponds to a desired ion dosage.

17. The method according to claim 16, further comprising continuing the plasma ion implantation of the substrate in response to a determination that there is an unacceptable amount of error between the measured radiation and the previously determined reflectance signature.

18. The method according to claim 16, further comprising stopping the plasma ion implantation of the substrate in response to a determination that there is a match between the measured radiation and the previously determined reflectance signature.

19. A method for determining dosage of ions in a plasma ion implantation of a substrate, comprising:
removing the substrate from a process chamber after the plasma ion implantation;
directing radiation onto the substrate;
measuring radiation reflected from the substrate; and
correlating the measured radiation reflected from the substrate to a dosage of ions implanted during the plasma ion implantation of the substrate.

20. The method according to claim 19, wherein the directing of radiation onto the substrate comprises directing the radiation onto the substrate at a normal angle of incidence.

21. The method according to claim 20, wherein the measuring of radiation reflected from the substrate comprises measuring radiation reflected at a normal angle of incidence from the substrate.

22. The method according to claim 19, wherein the directing of radiation onto the substrate comprises directing the radiation onto the substrate at an oblique angle of incidence before and after completing the plasma ion implantation.

23. The method according to claim 22, wherein the measuring of radiation reflected from the substrate comprises measuring radiation reflected at an oblique angle of incidence from the substrate.

24. The method according to claim 19, wherein the correlating of the measured radiation reflected from the substrate to a dosage of ions comprises comparing the measured radiation to a previously determined reflectance signature that corresponds to a desired ion dosage.

25. The method according to claim 19, further comprising obtaining a baseline radiation measurement prior to performing the plasma ion implantation in the process chamber.

26. A system for determining an ion implantation processing characteristic in a plasma ion implantation of a substrate, comprising:
a light source configured to direct radiation onto the substrate;
a detector configured to measure radiation reflected from the substrate; and
a processor configured to correlate the measured radiation reflected from the substrate to an ion implantation processing characteristic.

27. The system according to claim 26, wherein the light source is configured to direct the radiation onto the substrate at one of a normal angle of incidence or oblique angle of incidence during the plasma ion implantation.

28. The system according to claim 27, wherein the detector is configured to measure radiation reflected at one of a normal angle of incidence or oblique angle of incidence from the substrate.

29. The system according to claim 26, wherein the light source is configured to direct the radiation onto the substrate at one of a normal angle of incidence or oblique angle of incidence before and after completing the plasma ion implantation.

30. The system according to claim 29, wherein the detector is configured to measure radiation reflected at one of a normal angle of incidence oblique angle of incidence from the substrate.

31. The system according to claim 26, wherein the processor is configured to compare the measured radiation to a previously determined reflectance signature that corresponds to a desired ion implantation processing characteristic.

32. A plasma ion implantation system, comprising:
a process chamber configured to receive a substrate for plasma ion implantation;
a light source configured to direct radiation into the process chamber onto the substrate during the plasma ion implantation;
a detector configured to measure radiation reflected from the substrate through the process chamber; and
a processor configured to correlate the measured radiation reflected from the substrate to a dosage of ions implanted in the substrate.

33. The system according to claim 32, wherein the light source is configured to direct the radiation onto the substrate at one of a normal angle of incidence oblique angle of incidence.

34. The system according to claim 33, wherein the detector is configured to measure radiation reflected at one of a normal angle of incidence or oblique angle of incidence from the substrate.

35. The system according to claim 32, wherein the processor is configured to compare the measured radiation to a previously determined reflectance signature that corresponds to a desired ion dosage.

36. A plasma ion implantation system, comprising:
a process chamber configured to receive a substrate for plasma ion implantation;
a transfer chamber configured to receive the substrate after performing the plasma ion implantation in the process chamber;
a light source configured to direct radiation into the transfer chamber onto the substrate;
a detector configured to measure radiation reflected from the substrate through the transfer chamber; and
a processor configured to correlate the measured radiation reflected from the substrate to a dosage of ions implanted in the substrate.

37. The system according to claim 36, wherein the light source is configured to direct radiation onto the substrate at one of a normal angle of incidence or oblique angle of incidence.

38. The system according to claim 36, wherein the detector is configured to measure radiation reflected at one of a normal angle of incidence or oblique angle of incidence from the substrate.
